(19) United States
(12) Patent Application Publication
(10) Pub. No.: US 2014/0361637 A1
(43) Pub. Date: Dec. 11, 2014

(54) BUS SWITCHING CIRCUIT

(71) Applicant: Kabushiki Kaisha Toshiba, Tokyo (JP)

(72) Inventor: Akira TAKIBA, Kanagawa (JP)

(73) Assignee: KABUSHIKI KAISHA TOSHIBA, Tokyo (JP)

(21) Appl. No.: 14/170,915

(22) Filed: Feb. 3, 2014

(30) Foreign Application Priority Data
Jun. 6, 2013 (JP) 2013-120071

(51) Int. Cl. H03K 17/56

(52) U.S. Cl. CPC H03K 17/56
USPC 307/113

(57) ABSTRACT

A bus switching circuit includes a bus switching element which is connected between a first input/output terminal and a second input/output terminal, a first switching element which is connected between the second input/output terminal and a first voltage wiring, and a second switching element which is connected between the second input/output terminal and the first voltage wiring, the second switching element having an internal resistance to an electric current flowing therethrough which is larger than that of the first switching element. The bus switching circuit further includes a signal generation circuit which controls the first switching element and the second switching element by outputting the first control signal and the second control signal based on a result of the comparison between a first voltage applied to the first input/output terminal and a first threshold value.

### CROSS-REFERENCE TO RELATED APPLICATION

This application is based upon and claims the benefit of priority from Japanese Patent Application No. 2013-120071, filed Jun. 6, 2013, the entire contents of which are incorporated herein by reference.

### FIELD

Embodiments described herein relate to a bus switching circuit.

### BACKGROUND

With respect to a power source voltage for a system Large Scale Integration (LSI) represented by a Central Processing Unit (CPU) or a base band Integrated Circuit (IC), lowering of the power source voltage has been a goal so as to simplify the use process and reduce power consumption.

On the other hand, with respect to a power source voltage for a legacy system or an analog system, because of the necessity of maintaining compatibility, the progress in lowering the power source voltage has been slow.

As a result, in transmitting signals between circuits which differ in power source voltage, a bus switching circuit which performs the conversion of a signal level signal is required.

Such a related bus switching circuit includes an MOS transistor which is connected between an output side of a bus switching element and a power source wiring. By turning on the MOS transistor with a one-shot pulse signal, a signal level on an output side is raised to the level of a power source voltage. In this case, to transmit the signal at a high speed, it is necessary to shorten the pulse width of the pulse signal. However, when the pulse width of the pulse signal is shortened, because of ringing generated by the effect of a load capacitance or a wiring inductance, an output signal level may decrease below a predetermined level.

### DESCRIPTION OF THE DRAWINGS

FIG. 1 is a circuit diagram showing one example configuration of a bus switching circuit according to a first embodiment.

FIG. 2 is a waveform chart showing one example of waveforms of respective signals used in the bus switching circuit shown in FIG. 1.

FIG. 3 is a waveform chart showing another example of waveforms of respective signals used in the bus switching circuit shown in FIG. 1.

FIG. 4 is a waveform chart showing still another example of waveforms of respective signals used in the bus switching circuit shown in FIG. 1.

FIG. 5 is a waveform chart showing still another example of waveforms of respective signals used in the bus switching circuit shown in FIG. 1.

FIG. 6 is a block diagram showing one example configuration which includes systems which transmit or receive signals to and from the bus switching circuit shown in FIG. 1.

FIG. 7 is a circuit diagram showing one example configuration of a bus switching circuit according to a second embodiment.

FIG. 8 is a waveform chart showing one example of waveforms of respective signals used in the bus switching circuit shown in FIG. 7.

### DETAILED DESCRIPTION

According to an embodiment, there is provided a bus switching circuit which can transmit an output signal at a higher speed while making the output signal approximate a predetermined level.

In general, according to one embodiment, a bus switching circuit includes a bus switching element which is connected between a first input/output terminal and a second input/output terminal, a first switching element which is connected between the second input/output terminal and a first voltage wiring, and is controlled in response to a first control signal, a second switching element which is connected between the second input/output terminal and the first voltage wiring, and is controlled in response to a second control signal, the second switching element having an internal resistance to an electric current flowing therethrough which is larger than that of the first switching element, a signal generation circuit configured to control the first switching element and the second switching element by outputting the first control signal and the second control signal based on a result of a comparison between a first voltage applied to the first input/output terminal and a first threshold value, and a control circuit configured to switch the bus switching element on and off.

Hereinafter, respective embodiments are explained in conjunction with drawings.

### First Embodiment

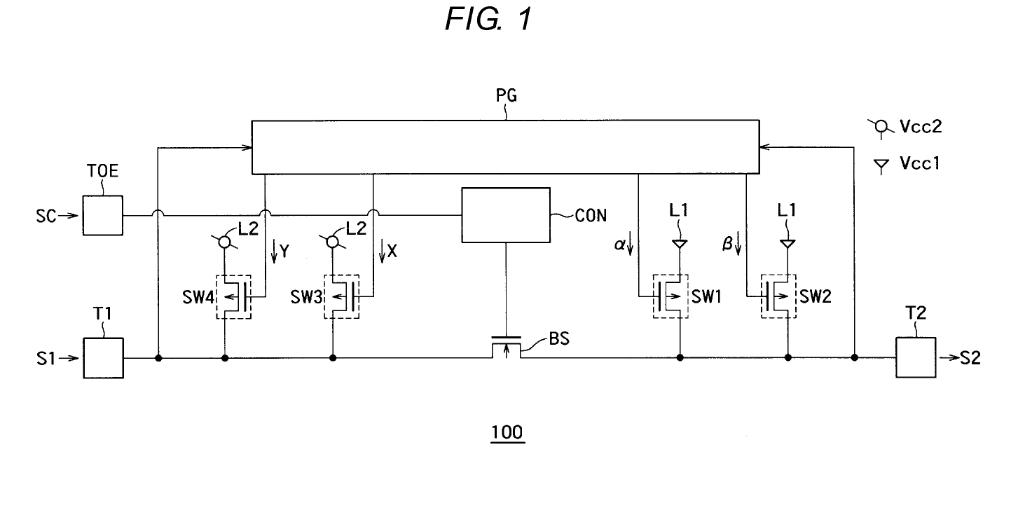

FIG. 1 is a circuit diagram showing one example configuration of a bus switching circuit 100 according to a first embodiment.

As shown in FIG. 1, the bus switching circuit 100 includes: a control terminal TOE; a first input/output terminal T1; a second input/output terminal T2; a bus switching element BS; a first switching element SW1; a second switching element SW2; a third switching element SW3; a fourth switching element SW4; a pulse signal generation circuit (signal generation circuit) PG; and a control circuit CON.

For example, a first logic circuit (not shown in the drawing) is connected to the first input/output terminal T1. A signal S1 is input to the first input/output terminal T1 from the first logic circuit, or a signal S1 is output to the first logic circuit through the first input/output terminal T1. The example shown in FIG. 1 describes the case where the signal S1 is input to the first input/output terminal T1 from the outside.

For example, a second logic circuit (not shown in the drawing) is connected to the second input/output terminal T2. A signal S2 is input to the second input/output terminal T2 from the second logic circuit, or a signal S2 is output to the second logic circuit through the second input/output terminal T2. The example shown in FIG. 1 describes the case where the signal S2 is output to the outside through the second input/output terminal T2.

A control signal SC for controlling one end of the bus switching element BS is input to the control terminal TOE.

The bus switching element BS is connected between the first input/output terminal T1 and the second input/output terminal T2.

For example, as shown in FIG. 1, the bus switching element BS is an nMOS transistor where a drain is connected to the first input/output terminal T1, a source is connected to the second input/output terminal T2, and a gate voltage is controlled by the control circuit CON.

The first switching element SW1 is connected between the second input/output terminal T2 and a first voltage wiring L1 to which a first power source voltage Vcc1 is applied. The first switching element SW1 is turned on or turned off in response to a first control pulse signal (first control signal) α.

In this embodiment, the first power source voltage Vcc1 is set higher than a ground voltage.

In this embodiment, as shown in FIG. 1, the first switching element SW1 is a pMOS transistor, for example.

The second switching element SW2 is connected between the second input/output terminal T2 and the first voltage wiring L1. The second switching element SW2 is turned on or turned off in response to a second control pulse signal (second control signal) β.

The second switching element SW2 is configured such that an electric current flows therethrough at a rate that is lower than the electric current flowing through the first switching element SW1.

In this embodiment, as shown in FIG. 1, the second switching element SW2 is a pMOS transistor, for example. In this case, for example, the second switching element (pMOS transistor) SW2 is configured to be smaller in size than the first switching element (pMOS transistor) SW1 so that the rate of the electric current flowing through the second switching element SW2 is lower than the electric current flowing through the first switching element SW1.

The third switching element SW3 is connected between the first input/output terminal T1 and the second voltage wiring L2 to which a second power source voltage Vcc2 is applied. The third switching element SW3 is turned on or turned off in response to a third control pulse signal (third control signal) X.

In this embodiment, as shown in FIG. 1, the third switching element SW3 is a pMOS transistor, for example.

The first power source voltage Vcc1 is set higher than the second power source voltage Vcc2, for example. However, the first power source voltage Vcc1 may be set to be equal to the second power source voltage Vcc2.

The fourth switching element SW4 is connected between the first input/output terminal T1 and the second voltage wiring L2. The fourth switching element SW4 is turned on or turned off in response to a fourth control pulse signal (fourth control signal) Y.

The fourth switching element SW4 is configured such that an electric current flows therethrough at a rate that is lower than the rate of an electric current flowing through the third switching element SW3.

In this embodiment, as shown in FIG. 1, the fourth switching element SW4 is a pMOS transistor, for example. In this case, for example, the fourth switching element (pMOS transistor) SW4 is configured to be smaller in size than the third switching element (pMOS transistor) SW3 so that the rate of the electric current flowing through the fourth switching element SW4 is lower than the electric current flowing through the third switching element SW3.

The pulse signal generation circuit PG generates a first control pulse signal α, and outputs the first control pulse signal α to the first switching element SW1. The pulse signal generation circuit PG also generates a second control pulse signal β, and outputs the second control pulse signal β to the second switching element SW2. The pulse signal generation circuit PG also generates a third control pulse signal X, and outputs the third control pulse signal X to the third switching element SW3. The pulse signal generation circuit PG also generates a fourth control pulse signal Y, and outputs the fourth control pulse signal Y to the fourth switching element SW4.

For example, at the time of transmitting a signal from the first input/output terminal T1 to the second input/output terminal T2, the pulse signal generation circuit PG compares a first voltage (a voltage of a signal S1) applied to the first input/output terminal T1 and a first threshold value to each other, and generates a first control pulse signal α and a second control pulse signal β based on the comparison result. Then, the pulse signal generation circuit PG outputs the generated first control pulse signal α and the generated second control pulse signal β thus controlling the first switching element SW1 with the first control pulse signal α and controlling the second switching element SW2 with the second control pulse signal β.

On the other hand, at the time of transmitting a signal from the second input/output terminal T2 to the first input/output terminal T1, the pulse signal generation circuit PG compares a second voltage (a voltage of a signal S2) applied to the second input/output terminal T2 and a second threshold value to each other, and generates a third control pulse signal X and a fourth control pulse signal Y based on the comparison result. Then, the pulse signal generation circuit PG outputs the generated third control pulse signal X and the generated fourth control pulse signal Y thus controlling the third switching element SW3 with the third control pulse signal X and controlling the fourth switching element SW4 with the fourth control pulse signal Y.

For example, the pulse signal generation circuit PG sets the first control pulse signal α and the third control pulse signal X as signals equivalent to each other, and sets the second control pulse signal β and the fourth control pulse signal Y as signals equivalent to each other. That is, the first switching element SW1 and the third switching element SW3 are controlled such that the first switching element SW1 and the third switching element SW3 perform the substantially same operation, while the second switching element SW2 and the fourth switching element SW4 are controlled such that the second switching element SW2 and the fourth switching element SW4 perform the substantially same operation.

The above-mentioned first threshold value is set to a value which is ½ of the first power source voltage Vcc1, for example. The above-mentioned second threshold value is set to a value which is ½ of the second power source voltage Vcc2, for example.

The control circuit CON controls the bus switching element BS in response to a control signal SC input through the control terminal TOE. The control signal SC is used for determining whether or not a signal S1 (or a signal S2) is to be transmitted between the first input/output terminal T1 and the second input/output terminal T2.

For example, the control circuit CON turns on the bus switching element BS when the signal S1 (or the signal S2) is to be transmitted between the first input/output terminal T1 and the second input/output terminal T2 in response to a control signal SC.

On the other hand, when the signal S1 (or the signal S2) is not to be transmitted between the first input/output terminal T1 and the second input/output terminal T2, the control circuit CON turns off the bus switching element BS in response to a control signal SC.

An example of the manner of operation of the bus switching circuit 100 having the above-mentioned configuration is explained.

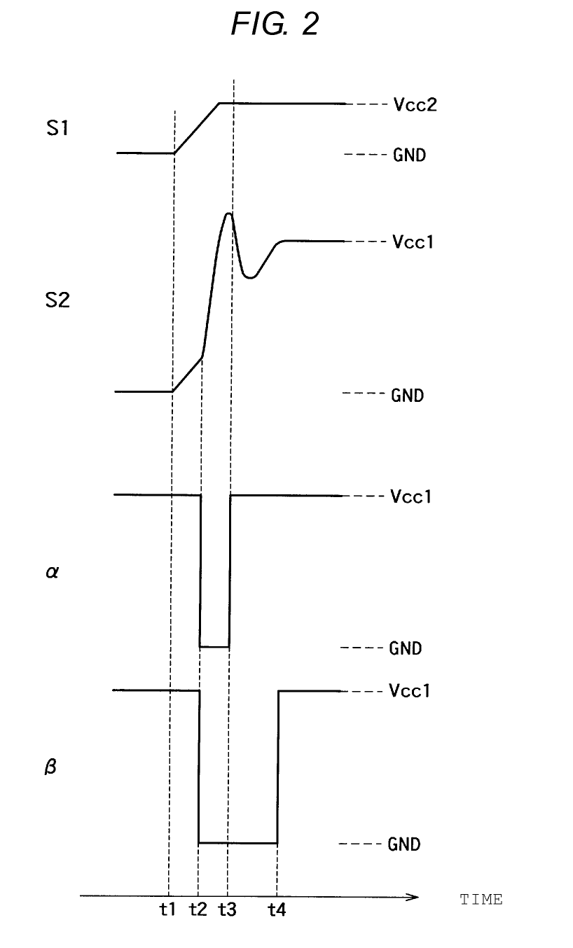

FIG. 2 is a waveform chart showing one example of waveforms of respective signals used in the bus switching circuit 100 shown in FIG. 1. FIG. 2 shows the case where a signal is transmitted from the first input/output terminal T1 to the second input/output terminal T2.

As shown in FIG. 2, before a point of time t1, a first signal (first voltage) S1 and a second signal (second voltage) S2 are at “Low” level (ground voltage GND).

A first control pulse signal α and a second control pulse signal β are at “High” level (first power source voltage Vcc1). Accordingly, the first switching element SW1 and the second switching element SW2 are in an OFF state.

The control circuit CON turns on the bus switching element BS in response to the control signal SC.

That is, before the point of time t1, the bus switching circuit 100 is in a state where the bus switching element BS is turned on, and the first switching element SW1 and the second switching element SW2 are turned off.

Then, in the above-mentioned state, at the point of time t1, the change of the level of the first signal (first voltage) S1 input to the first input/output terminal T1 from “Low” level (ground voltage GND) to “High” level (second power source voltage Vcc2) starts.

At this point of time, since the bus switching element BS is turned on, due to a change in the first signal (first voltage) S1, the change of the level of the second signal S2 of the second input/output terminal T2 from “Low” level to “High” level (first power source voltage Vcc1) starts.

That is, during a period from the point of time t1 to a point of time t2, the input signal is transmitted from the first input/output terminal T1 as is.

Thereafter, when the first signal (first voltage) S1 exceeds a first threshold value, the pulse signal generation circuit PG changes the first control pulse signal α and the second control pulse signal β to “Low” level (ground voltage) thus turning on the first switching element SW1 and the second switching element SW2 simultaneously (point of time: t2).

Accordingly, the second signal (second voltage) S2 of the second input/output terminal T2 is raised to the first power source voltage Vcc1 so that an output signal at “High” level is output through the second input/output terminal T2. That is, a transmission speed of the signal is increased.

Thereafter, the pulse signal generation circuit PG changes the first control pulse signal α to “High” level (first power source voltage Vcc1) thus turning off the first switching element SW1 (point of time: t3).

In the example shown in FIG. 2, after the completion of the change of the level of the first signal S1 to “High” level (second power source voltage Vcc2), the pulse signal generation circuit PG changes the first control pulse signal α to “High” level (first power source voltage Vcc1).

In this manner, after the first signal S1 changes to a desired level, the first switching element SW1 having higher drive capability is turned off. Accordingly, by setting drive capability of a driver circuit which outputs the first signal S1 higher than drive capability of the second switching element SW2, inputting of a next signal to the first input/output terminal T1 becomes possible. That is, the high-speed transmission of a signal in the bus switching circuit 100 becomes possible.

The second switching element SW2 having lower drive capability is kept in an ON state. Accordingly, it is possible to suppress a phenomenon that the level of the second signal (second voltage) S2 of the second input/output terminal T2 is lowered due to ringing generated because of a load capacitance (not shown in the drawing) connected to the second input/output terminal T2 or a wiring inductance.

Thereafter, the pulse signal generation circuit PG changes the second control pulse signal β to “High” level (first power source voltage Vcc1) thus turning off the second switching element SW2 (point of time: t4).

In the example shown in FIG. 2, after the completion of the change of the level of the second signal S2 to “High” level (second power source voltage Vcc2), the pulse signal generation circuit PG changes the second control pulse signal β to “High” level (first power source voltage Vcc1).

In this manner, in a state where the bus switching element BS is turned on and the first switching element SW1 and the second switching element SW2 are turned off, when the first signal S1 (first voltage) exceeds the first threshold value, the pulse signal generation circuit PG turns on the first switching element SW1 only for the first period (from time t2 to time t3), turns on the second switching element SW2 after starting the first period (time t2 in the example shown in FIG. 2), and turns off the second switching element SW2 after the completion of the first period (time t4 in the example shown in FIG. 2).

Due to such an operation of the bus switching circuit 100, it is possible to transmit an output signal at a higher speed while making the output signal approximate a predetermined level.

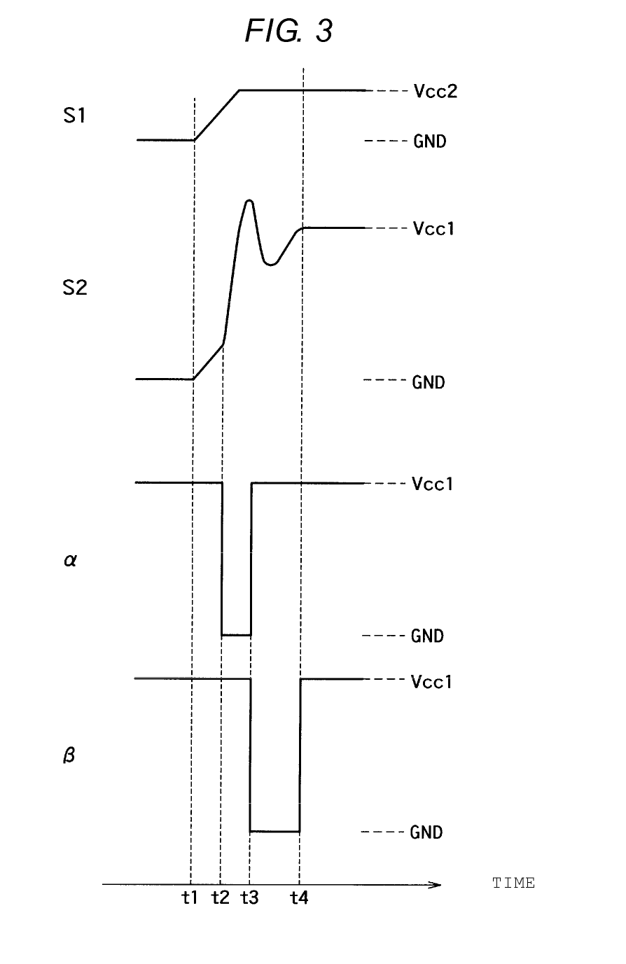

Next, FIG. 3 is a waveform chart showing another example of waveforms of the respective signals used in the bus switching circuit 100 shown in FIG. 1. FIG. 3 shows the case where a signal is transmitted from the first input/output terminal T1 to the second input/output terminal T2.

As shown in FIG. 3, a state of the bus switching circuit 100 before a point of time t1 is substantially equal to the corresponding state described previously in conjunction with FIG. 2. That is, before a point of time t1, the bus switching circuit 100 is in a state where a bus switching element BS is turned on, and a first switching element SW1 and a second switching element SW2 are turned off.

Then, in the above-mentioned state, at the point of time t1, the change of the level of the first signal (first voltage) S1 input to the first input/output terminal T1 from “Low” level (ground voltage GND) to “High” level (second power source voltage Vcc2) starts.

At this point of time, since the bus switching element BS is turned on, due to a change in the first signal (first voltage) S1, the change of the level of the second signal S2 of the second input/output terminal T2 from “Low” level to “High” level (first power source voltage Vcc1) starts.

That is, during a period from the point of time t1 to the point of time t2, the input signal is transmitted from the first input/output terminal T1 as is.

Thereafter, when the first signal (first voltage) S1 exceeds the first threshold value, the pulse signal generation circuit PG changes the first control pulse signal α to “Low” level (ground voltage) thus turning on the first switching element SW1 having higher drive capability (point of time: t2).

Accordingly, the second signal (second voltage) S2 of the second input/output terminal T2 is raised to the first power source voltage Vcc1 so that an output signal at “High” level is output through the second input/output terminal T2. That is, a transmission speed of the signal is increased.

Thereafter, the pulse signal generation circuit PG changes the first control pulse signal α to “High” level (first power source voltage Vcc1), and changes the second control pulse signal β to “Low” level (ground voltage GND) thus turning off the first switching element SW1 and, at the same time, turning on the second switching element SW2 (point of time: t3).

In the example shown in FIG. 3, after the completion of the change of the level of the first signal S1 to “High” level (second power source voltage Vcc2), the pulse signal generation circuit PG changes the first control pulse signal α to “High” level (first power source voltage Vcc1).

The second switching element SW2 having lower drive capability is turned on. Accordingly, it is possible to suppress a phenomenon that the level of the second signal (second voltage) S2 of the second input/output terminal T2 is lowered due to ringing generated because of a load capacitance (not shown in the drawing) connected to the second input/output terminal T2 or a wiring inductance.

In this manner, after the first signal S1 changes to a desired level, the first switching element SW1 having higher drive capability is turned off. Accordingly, by setting drive capability of a driver circuit which outputs the first signal S1 higher than drive capability of the second switching element SW2, inputting of a next signal to the first input/output terminal T1 becomes possible. That is, the high-speed transmission of a signal in the bus switching circuit 100 becomes possible.

Thereafter, the pulse signal generation circuit PG changes the second control pulse signal β to “High” level (first power source voltage Vcc1) thus turning off the second switching element SW2 (point of time: t4).

In the example shown in FIG. 3, after the completion of the change of the level of the second signal S2 to “High” level (second power source voltage Vcc2), the pulse signal generation circuit PG changes the second control pulse signal β to “High” level (first power source voltage Vcc1).

In this manner, in a state where the bus switching element BS is turned on and the first switching element SW1 and the second switching element SW2 are turned off, when the first signal S1 (first voltage) exceeds the first threshold value, the pulse signal generation circuit PG turns on the first switching element SW1 only for the first period (from a point of time t2 to a point of time t3), turns on the second switching element SW2 after starting the first period (the point of time t3 in the example shown in FIG. 3), and turns off the second switching element SW2 after the completion of the first period (a point of time t4 in the example shown in FIG. 3).

Due to such an operation of the bus switching circuit 100, it is possible to transmit an output signal at a higher speed while making the output signal approximate a predetermined level.

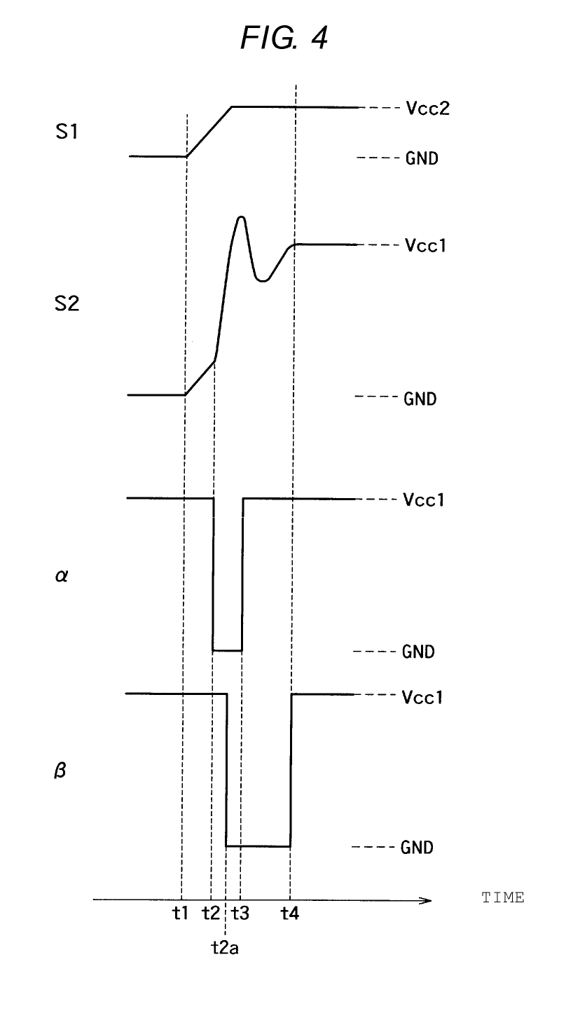

FIG. 4 is a waveform chart showing another example of waveforms of respective signals used in the bus switching circuit 100 shown in FIG. 1. FIG. 4 shows the case where a signal is transmitted from the first input/output terminal T1 to the second input/output terminal T2.

As shown in FIG. 4, a state of the bus switching circuit 100 before a point of time t1 is substantially equal to the corresponding state described previously in conjunction with FIG. 2. That is, before a point of time t1, the bus switching circuit 100 is in a state where the bus switching element BS is turned on, and the first switching element SW1 and the second switching element SW2 are turned off.

Then, in the above-mentioned state, at the point of time t1, the change of the level of the first signal (first voltage) S1 input to the first input/output terminal T1 from “Low” level (ground voltage GND) to “High” level (second power source voltage Vcc2) starts.

At this point of time, since the bus switching element BS is turned on, due to a change in the first signal (first voltage) S1, the change of the level of the second signal S2 of the second input/output terminal T2 from “Low” level to “High” level (first power source voltage Vcc1) starts.

That is, during a period from the point of time t1 to the point of time t2, the input signal is transmitted from the first input/output terminal T1 as is.

Thereafter, when the first signal (first voltage) S1 exceeds the first threshold value, the pulse signal generation circuit PG changes the first control pulse signal α to “Low” level (ground voltage) thus turning on the first switching element SW1 having higher drive capability (point of time: t2).

Accordingly, the second signal (second voltage) S2 of the second input/output terminal T2 is raised to the first power source voltage Vcc1 so that an output signal at “High” level is output through the second input/output terminal T2. That is, a transmission speed of the signal is increased.

Thereafter, the pulse signal generation circuit PG changes the second control pulse signal β to “Low” level (ground voltage GND) thus turning on the second switching element SW2 (point of time: t2a).

Thereafter, the pulse signal generation circuit PG changes the first control pulse signal α to “High” level (first power source voltage Vcc1) thus turning off the first switching element SW1 (point of time: t3).

In the example shown in FIG. 4, after the completion of the change of the level of the first signal S1 to “High” level (second power source voltage Vcc2), the pulse signal generation circuit PG changes the first control pulse signal α to “High” level (first power source voltage Vcc1).

The second switching element SW2 having lower drive capability is kept in an ON state. Accordingly, it is possible to suppress a phenomenon that the level of the second signal (second voltage) S2 of the second input/output terminal T2 is lowered due to ringing generated because of a load capacitance (not shown in the drawing) connected to the second input/output terminal T2 or a wiring inductance.

In this manner, after the first signal S1 changes to a desired level, the first switching element SW1 having higher drive capability is turned off. Accordingly, by setting drive capability of a driver circuit which outputs the first signal S1 higher than drive capability of the second switching element SW2, inputting of a next signal to the first input/output terminal T1 becomes possible. That is, the high-speed transmission of a signal in the bus switching circuit 100 becomes possible.

Thereafter, the pulse signal generation circuit PG changes the second control pulse signal β to “High” level (first power source voltage Vcc1) thus turning off the second switching element SW2 (point of time: t4).

In the example shown in FIG. 4, after the completion of the change of the level of the second signal S2 to “High” level (second power source voltage Vcc2), the pulse signal generation circuit PG changes the second control pulse signal β to “High” level (first power source voltage Vcc1).

In this manner, in a state where the bus switching element BS is turned on and the first switching element SW1 and the second switching element SW2 are turned off, when the first signal S1 (first voltage) exceeds the first threshold value, the pulse signal generation circuit PG turns on the first switching element SW1 only for the first period (from a point of time t2 to a point of time t3), turns on the second switching element SW2 after starting the first period (the point of time t2a in the example shown in FIG. 4), and turns off the second switching element SW2 after the completion of the first period (a point of time t4 in the example shown in FIG. 4).

Due to such an operation of the bus switching circuit 100, it is possible to transmit an output signal at a higher speed while making the output signal approximate a predetermined level.

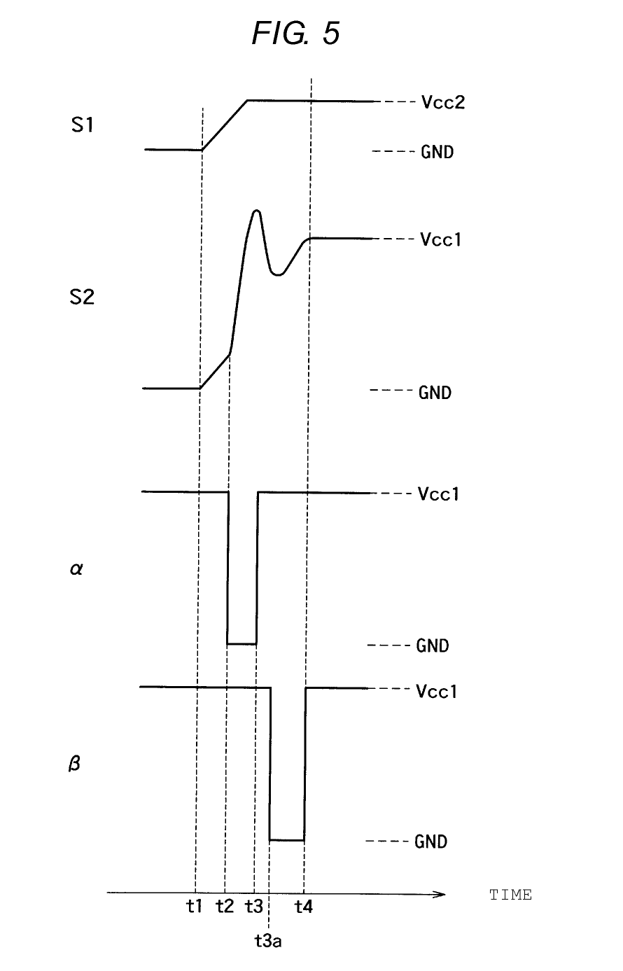

FIG. 5 is a waveform chart showing still another example of waveforms of respective signals used in the bus switching circuit 100 shown in FIG. 1. FIG. 5 shows the case where a signal is transmitted from the first input/output terminal T1 to the second input/output terminal T2.

As shown in FIG. 5, a state of the bus switching circuit 100 before a point of time t1 is substantially equal to the corresponding state described previously in conjunction with FIG. 2. That is, before a point of time t1, the bus switching circuit 100 is in a state where the bus switching element BS is turned on, and the first switching element SW1 and the second switching element SW2 are turned off.

Then, in the above-mentioned state, at the point of time t1, the change of the level of the first signal (first voltage) S1 input to the first input/output terminal T1 from “Low” level (ground voltage GND) to “High” level (second power source voltage Vcc2) starts.

At this point of time, since the bus switching element BS is turned on, due to a change in the first signal (first voltage) S1, the change of the level of the second signal S2 of the second input/output terminal T2 from “Low” level to “High” level (first power source voltage Vcc1) starts.

That is, during a period from the point of time t1 to a point of time t2, the input signal is transmitted from the first input/output terminal T1 as is.

Thereafter, when the first signal (first voltage) S1 exceeds the first threshold value, the pulse signal generation circuit PG changes the first control pulse signal α to “Low” level (ground voltage) thus turning on the first switching element SW1 having higher drive capability (point of time: t2).

Accordingly, the second signal (second voltage) S2 of the second input/output terminal T2 is raised to the first power source voltage Vcc1 so that an output signal at “High” level is output through the second input/output terminal T2. That is, a transmission speed of the signal is increased.

Thereafter, the pulse signal generation circuit PG changes the first control pulse signal α to “High” level (first power source voltage Vcc1) thus turning off the first switching element SW1 (point of time: t3).

In the example shown in FIG. 5, after the completion of the change of the level of the first signal S1 to “High” level (second power source voltage Vcc2), the pulse signal generation circuit PG changes the first control pulse signal α to “High” level (first power source voltage Vcc1).

Thereafter, the pulse signal generation circuit PG changes the second control pulse signal β to “Low” level (ground voltage GND) thus turning on the second switching element SW2 (point of time: t3a).

In this manner, the first switching element SW1 having higher drive capability is turned off, and thereafter, the second switching element SW2 having lower drive capability is turned on. Accordingly, it is possible to suppress a phenomenon that the level of the second signal (second voltage) S2 of the second input/output terminal T2 is lowered due to ringing generated because of a load capacitance (not shown in the drawing) connected to the second input/output terminal T2 or a wiring inductance.

Thereafter, the pulse signal generation circuit PG changes the second control pulse signal β to “High” level (first power source voltage Vcc1) thus turning off the second switching element SW2 (point of time: t4).

In the example shown in FIG. 5, after the completion of the change of the level of the second signal S2 to “High” level (second power source voltage Vcc2), the pulse signal generation circuit PG changes the second control pulse signal β to “High” level (first power source voltage Vcc1).

In this manner, in a state where the bus switching element BS is turned on and the first switching element SW1 and the second switching element SW2 are turned off, when the first signal S1 (first voltage) exceeds the first threshold value, the pulse signal generation circuit PG turns on the first switching element SW1 only for the first period (from a point of time t2 to a point of time t3), turns on the second switching element SW2 after starting the first period (the point of time t3a in the example shown in FIG. 5), and turns off the second switching element SW2 after the completion of the first period (a point of time t4 in the example shown in FIG. 5).

More particularly, after the first signal S1 changes to a desired level, the first switching element SW1 having higher drive capability is turned off. Accordingly, by setting drive capability of a driver circuit which outputs the first signal S1 higher than drive capability of the second switching element SW2, inputting of a next signal to the first input/output terminal T1 becomes possible. That is, the high-speed transmission of a signal in the bus switching circuit 100 becomes possible.

Due to such an operation of the bus switching circuit 100, it is possible to transmit an output signal at a higher speed while making the output signal approximate a predetermined level.

As described heretofore, in the examples shown in FIG. 2 to FIG. 5, the explanation has been made by focusing on the control of the first and second switching elements SW1, SW2 in the case where a signal is transmitted to the second input/output terminal T2 from the first input/output terminal T1. Then, when a signal is transmitted from the second input/output terminal T2 to the first input/output terminal T1, the third switching element SW3 is controlled in the same manner as the first switching element SW1, and the fourth switching element SW4 is controlled in the same manner as the second switching element SW2.

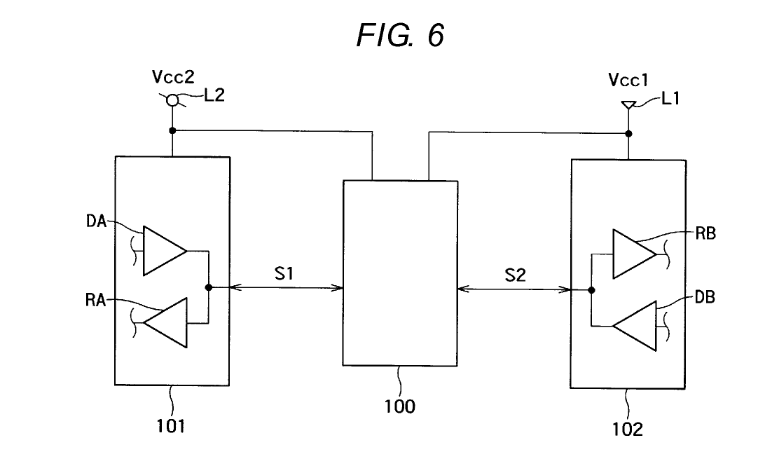

FIG. 6 is a block diagram showing one example configuration which includes systems 101, 102 which transmit or receive signals to and from the bus switching circuit 100 shown in FIG. 1.

As shown in FIG. 6, transmission/reception of the first signal S1 is performed between the system 101 and the bus switching circuit 100.

The system 101 includes: a driver circuit DA which outputs a signal to the first input/output terminal T1 of the bus switching circuit 100; and a receiver circuit RA which receives the signal output through the first input/output terminal T1 of the bus switching circuit 100. These driver circuit DA and receiver circuit RA are included in the logic circuit described previously which is connected to the first input/output terminal T1.

Drive capability of the second switching element SW2 in the bus switching circuit 100 is set higher than drive capability of the driver circuit DA.

For example, after the first signal S1 changes to a desired level as shown in FIG. 2, the first switching element SW1 having higher drive capability than the driver circuit DA is turned off. As described previously, drive capability of the driver circuit DA which outputs the first signal S1 is set higher than drive capability of the second switching element SW2 and hence, the bus switching circuit 100 is brought into a state where the driver circuit DA can invert the first signal S1. That is, inputting of a next signal to the first input/output terminal T1 from the driver circuit DA becomes possible.

Accordingly, as described previously, the high-speed transmission of a signal from the first input/output terminal T1 to the second input/output terminal T2 becomes possible.

As shown in FIG. 6, transmission/reception of signals is performed between the system 102 and the bus switching circuit 100.

The system 102 includes a driver circuit DB which outputs a signal to the second input/output terminal T2 of the bus switching circuit 100; and a receiver circuit RB which receives the signal output through the second input/output terminal T2 of the bus switching circuit 100. These driver circuit DB and receiver circuit RB are included in the logic circuit described previously which is connected to the second input/output terminal T2.

Drive capability of the fourth switching element SW4 in the bus switching circuit 100 is set higher than drive capability of the driver circuit DB.

By setting drive capability of the fourth switching element SW4 in this manner, the high-speed transmission of a signal to the first input/output terminal T1 from the second input/output terminal T2 becomes possible.

As described above, according to the bus switching circuit of the first embodiment, it is possible to transmit an output signal at a higher speed while making the output signal approximate a predetermined level.

### Second Embodiment

In the above described first embodiment, the explanation is made with respect to the example of the bus switching circuit where the first to fourth switching elements are pMOS transistors. In the configuration of the first embodiment, a signal is made to rise at a high speed.

On the other hand, in a second embodiment, the explanation is made with respect to the example of a bus switching circuit where the first to fourth switching elements are nMOS transistors. In the configuration of the second embodiment, a signal is made to fall at a high speed.

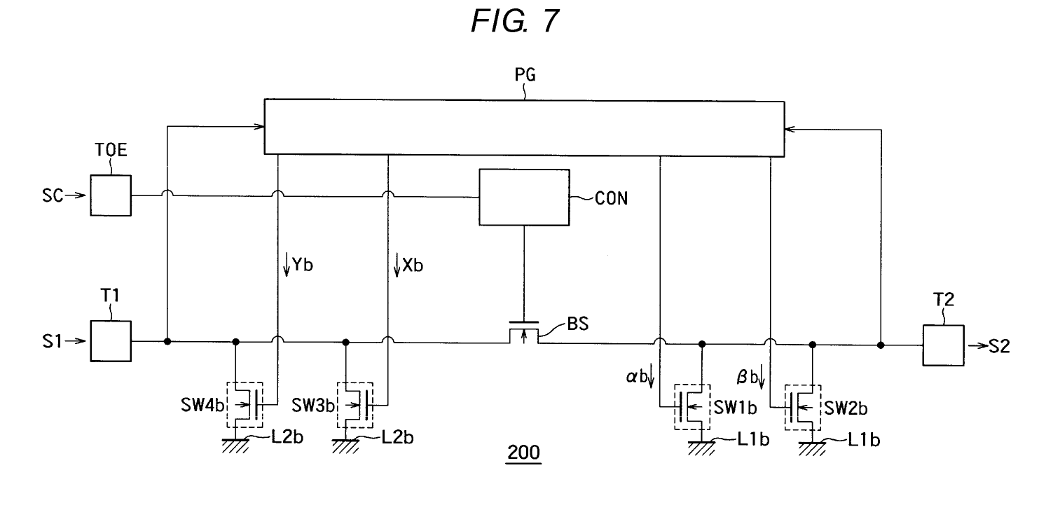

FIG. 7 is a circuit diagram showing one example configuration of a bus switching circuit 200 according to the second embodiment. In FIG. 7, symbols identical with symbols in FIG. 1 indicate configuration substantially equal to the corresponding configuration of the first embodiment.

As shown in FIG. 7, the bus switching circuit 200 includes: a control terminal TOE; a first input/output terminal T1; a second input/output terminal T2; a bus switching element BS; a first switching element SW1b; a second switching element SW2b; a third switching element SW3b; a fourth switching element SW4b; a pulse signal generation circuit PG; and a control circuit CON.

The first switching element SW1b is connected between the second input/output terminal T2 and a first voltage wiring Lib to which a first power source voltage (a ground voltage in this embodiment) is applied. The first switching element SW1 is turned on or turned off in response to the first control pulse signal α.

In this embodiment, as shown in FIG. 7, the first switching element SW1b is an nMOS transistor, for example.

The second switching element SW2b is connected between the second input/output terminal T2 and the first voltage wiring Lib. The second switching element SW2b is turned on or turned off in response to the second control pulse signal βb.

The second switching element SW2b is configured such that an electric current flows therethrough at a rate that is lower than the electric current flowing through the first switching element SW1b.

In this embodiment, as shown in FIG. 7, the second switching element SW2b is an nMOS transistor, for example. In this case, for example, the second switching element (nMOS transistor) SW2b is configured to be smaller in size than the first switching element (nMOS transistor) SW1b so that the rate of the electric current flowing through the second switching element SW2b is lower than the electric current flowing through the first switching element SW1b.

The third switching element SW3b is connected between the first input/output terminal T1 and the second voltage wiring L2b to which a second power source voltage (a ground voltage in this embodiment) is applied. The third switching element SW3b is turned on or turned off in response to the third control pulse signal Xb.

In this embodiment, as shown in FIG. 7, the third switching element SW3b is an nMOS transistor, for example.

As described above, in this embodiment, the first power source voltage is set to be equal to the second power source voltage.

The fourth switching element SW4b is connected between the first input/output terminal T1 and the second voltage wiring L2b. The fourth switching element SW4b is turned on or turned off in response to the fourth control pulse signal Yb.

The fourth switching element SW4b is configured such that an electric current flows therethrough at a rate that is lower than the rate of an electric current flowing through the third switching element SW3b.

In this embodiment, as shown in FIG. 7, the fourth switching element SW4b is an nMOS transistor, for example. In this case, for example, the fourth switching element (nMOS transistor) SW4b is configured to be smaller in size than the third switching element (nMOS transistor) SW3b so that the rate of the electric current flowing through the fourth switching element SW4 is lower than the electric current flowing through the third switching element SW3.

The pulse signal generation circuit PG generates a first control pulse signal αb, and outputs the first control pulse signal αb to the first switching element SW1b. The pulse signal generation circuit PG also generates a second control pulse signal βb and outputs the second control pulse signal βb to the second switching element SW2b. The pulse signal generation circuit PG also generates a third control pulse signal Xb, and outputs the third control pulse signal Xb to the third switching element SW3b. The pulse signal generation circuit PG also generates a fourth control pulse signal Yb, and outputs the fourth control pulse signal Yb to the fourth switching element SW4b.

For example, at the time of transmitting a signal from the first input/output terminal T1 to the second input/output terminal T2, the pulse signal generation circuit PG compares a first voltage (a voltage of a signal S1) applied to the first input/output terminal T1 and a first threshold value to each other, and generates a first control pulse signal αb and a second control pulse signal βb based on the comparison result. Then, the pulse signal generation circuit PG outputs the generated first control pulse signal αb and the generated second control pulse signal βb thus controlling the first switching element SW1b with the first control pulse signal αb and controlling the second switching element SW2b with the second control pulse signal βb.

On the other hand, at the time of transmitting a signal to the first input/output terminal T1 from the second input/output terminal T2, the pulse signal generation circuit PG compares a second voltage (a voltage of a signal S2) applied to the second input/output terminal T2 and a second threshold value to each other, and generates a third control pulse signal Xb and a fourth control pulse signal Yb based on the comparison result. Then, the pulse signal generation circuit PG outputs the generated third control pulse signal Xb and the generated fourth control pulse signal Yb thus controlling the third switching element SW3b with the third control pulse signal Xb and controlling the fourth switching element SW4b with the fourth control pulse signal Yb.

Other constitutions of the bus switching circuit 200 of the second embodiment are substantially equal to the corresponding constitutions of the first embodiment.

One example of the manner of operation of the bus switching circuit 200 having the above-mentioned configuration is explained.

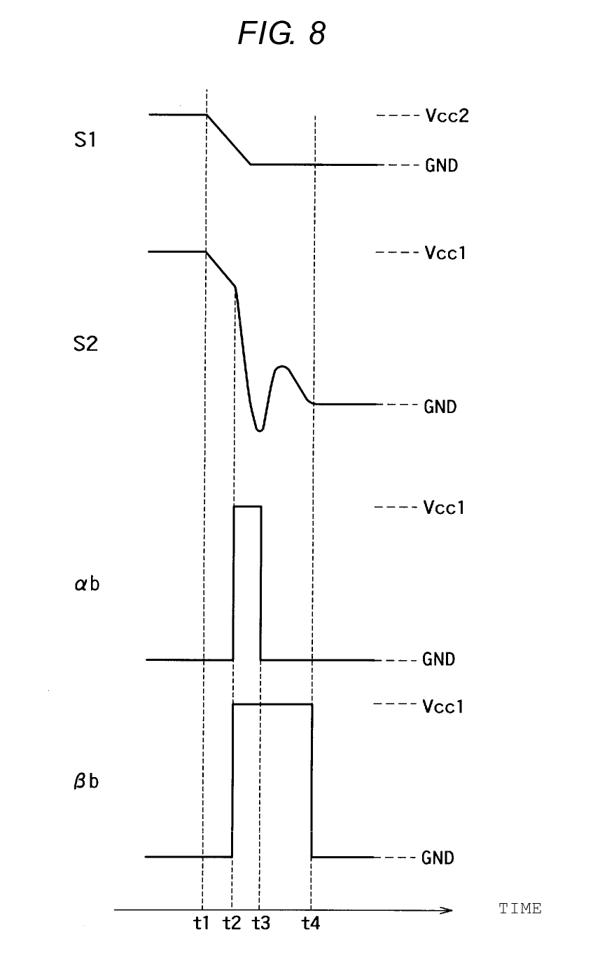

FIG. 8 is a waveform chart showing one example of waveforms of respective signals used in the bus switching circuit 200 shown in FIG. 7. FIG. 8 shows the case where a signal is transmitted from the first input/output terminal T1 to the second input/output terminal T2.

As shown in FIG. 8, before a point of time t1, a first signal (first voltage) S1 and a second signal (second voltage) S2 are at “Low” level (ground voltage GND).

A first control pulse signal αb and a second control pulse signal βb are at “Low” level (ground voltage GND). Accordingly, the first switching element SW1b and the second switching element SW2b are in an OFF state.

The control circuit CON turns on the bus switching element BS in response to the control signal SC.

That is, before a point of time t1, the bus switching circuit 100 is in a state where the bus switching element BS is turned on, and the first switching element SW1b and the second switching element SW2b are turned off.

Then, in the above-mentioned state, at the point of time t1, the change of the level of the first signal (first voltage) S1 input to the first input/output terminal T1 from “High” level (second power source voltage Vcc2) to “Low” level (ground voltage GND) starts.

At this point of time, since the bus switching element BS is in an ON state, due to a change in the first signal (first voltage) S1, the change of the level of the second signal S2 of the second input/output terminal T2 from “High” level (first power source voltage Vcc1) to “Low” level (ground voltage GND) starts.

That is, during a period from the point of time t1 to a point of time t2, the input signal is transmitted from the first input/output terminal T1 as it is.

Thereafter, when the first signal (first voltage) S1 is lowered below the first threshold value, the pulse signal generation circuit PG changes the first control pulse signal αb and the second control pulse signal βb to “High” level (first power source voltage Vcc1) thus turning on the first switching element SW1 and the second switching element SW2 simultaneously (point of time: t2).

Accordingly, the second signal (second voltage) S2 of the second input/output terminal T2 is lowered to a ground voltage GND so that an output signal at “Low” level is output through the second input/output terminal T2. That is, a transmission speed of the signal is increased.

Thereafter, the pulse signal generation circuit PG changes the first control pulse signal αb to “Low” level (ground voltage GND) thus turning off the first switching element SW1 (point of time: t3).

In the example shown in FIG. 8, after the completion of the change of the level of the first signal S1 to “Low” level (ground voltage GND), the pulse signal generation circuit PG changes the first control pulse signal αb to “Low” level (ground voltage GND).

The second switching element SW2 having lower drive capability is kept in an ON state. Accordingly, it is possible to suppress a phenomenon that the level of the second signal (second voltage) S2 of the second input/output terminal T2 changes due to ringing generated because of a load capacitance (not shown in the drawing) connected to the second input/output terminal T2 or a wiring inductance.

In this manner, after the first signal S1 changes to a desired level, the first switching element SW1 having higher drive capability is turned off. Accordingly, by setting drive capability of a driver circuit which outputs the first signal S1 higher than drive capability of the second switching element SW2, inputting of a next signal to the first input/output terminal T1 becomes possible. That is, the high-speed transmission of a signal in the bus switching circuit 200 becomes possible.

Thereafter, the pulse signal generation circuit PG changes the second control pulse signal βb to “Low” level (ground voltage GND) thus turning off the second switching element SW2 (point of time: t4).

In the example shown in FIG. 8, after the completion of the change of the level of the second signal S2 to “Low” level (ground voltage GND), the pulse signal generation circuit PG changes the second control pulse signal βb to “Low” level (ground voltage GND).

In this manner, in a state where the bus switching element BS is turned on and the first switching element SW1 and the second switching element SW2 are turned off, when the first signal S1 (first voltage) is lowered below the first threshold value, the pulse signal generation circuit PG turns on the first switching element SW1 only for the first period (from a point of time t2 to a point of time t3), turns on the second switching element SW2 after starting the first period (time t2 in the example shown in FIG. 8), and turns off the second switching element SW2 after the completion of the first period (a point of time t4 in the example shown in FIG. 8).

Due to such an operation of the bus switching circuit 200, it is possible to transmit an output signal at a higher speed while making the output signal approximate a predetermined level.

As described above, according to the bus switching circuit of the second embodiment, in the same manner as the first embodiment, it is possible to transmit an output signal at a higher speed while making the output signal approximate a predetermined level.

The configuration of the bus switching circuit of the first embodiment and the configuration of the bus switching circuit of the second embodiment may be combined with each other. Due to such a constitution, a signal is made to rise or fall at a high speed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A bus switching circuit comprising:
a bus switching element which is connected between a first input/output terminal and a second input/output terminal;
a first switching element which is connected between the second input/output terminal and a first voltage wiring, and is controlled in response to a first control signal;
a second switching element which is connected between the second input/output terminal and the first voltage wiring, and is controlled in response to a second control signal, the second switching element having an internal resistance to an electric current flowing therethrough which is larger than that of the first switching element;
a signal generation circuit configured to control the first switching element and the second switching element by outputting the first control signal and the second control signal based on a result of a comparison between a first voltage applied to the first input/output terminal and a first threshold value; and
a control circuit configured to switch the bus switching element on and off.

2. The bus switching circuit according to claim 1, wherein a size of the second switching element is smaller than a size of the first switching element.

3. The bus switching circuit according to claim 1, further comprising:
a third switching element which is connected between the first input/output terminal and a second voltage wiring, and is controlled in response to a third control signal; and
a fourth switching element which is connected between the first input/output terminal and the second voltage wiring, and is controlled in response to a fourth control signal, the fourth switching element having an internal resistance to an electric current flowing therethrough which is larger than that of the third switching element,
wherein the signal generation circuit is further configured to control the third switching element and the fourth switching element by outputting the third control signal and the fourth control signal based on a result of a comparison between a second voltage applied to the second input/output terminal and a second threshold value.

4. The bus switching circuit according to claim 3, wherein a size of the fourth switching element is smaller than a size of the third switching element.

5. The bus switching circuit according to claim 3, wherein the control circuit switches the bus switching element on when a signal is to be transmitted between the first input/output terminal and the second input/output terminal.

6. The bus switching circuit according to claim 3, wherein the first threshold value is greater than the second threshold value.

7. The bus switching circuit according to claim 1, wherein
in a state where the bus switching element is turned on and the first switching element and the second switching element are turned off,
when the first voltage exceeds the first threshold value, the signal generation circuit turns on the first switching element for a first period, turns on the second switching element after start of the first period, and turns off the second switching element after expiration of the first period.

8. The bus switching circuit according to claim 7, wherein the signal generation circuit turns on the second switching element upon expiration of the first period.

9. The bus switching circuit according to claim 7, wherein the signal generation circuit turns on the second switching element prior to expiration of the first period.

10. The bus switching circuit according to claim 7, wherein the signal generation circuit turns on the second switching element after expiration of the first period.

11. The bus switching circuit according to claim 7, wherein the first and second switching elements are pMOS transistors.

12. The bus switching circuit according to claim 1, wherein
in a state where the bus switching element is turned on and the first switching element and the second switching element are turned off,
when the first voltage exceeds the first threshold value, the signal generation circuit turns on the first switching element and the second switching element simultaneously, and thereafter, turns off the first switching element, and thereafter, turns off the second switching element.

13. The bus switching circuit according to claim 1, wherein
in a state where the bus switching element is turned on and the first switching element and the second switching element are turned off,
when the first voltage falls below the first threshold value, the signal generation circuit turns on the first switching element for a first period, turns on the second switching element after start of the first period, and turns off the second switching element after expiration of the first period.

14. The bus switching circuit according to claim 13, wherein the signal generation circuit turns on the second switching element upon expiration of the first period.

15. The bus switching circuit according to claim 13, wherein the signal generation circuit turns on the second switching element prior to expiration of the first period.

16. The bus switching circuit according to claim 13, wherein the signal generation circuit turns on the second switching element after expiration of the first period.

17. The bus switching circuit according to claim 13, wherein the first and second switching elements are pMOS transistors.

18. The bus switching circuit according to claim 1, wherein
in a state where the bus switching element is turned on and the first switching element and the second switching element are turned off,
when the first voltage falls below the first threshold value, the signal generation circuit turns on the first switching element and the second switching element simultaneously, and thereafter, turns off the first switching element, and thereafter, turns off the second switching element.

19. A bus switching circuit comprising:
a bus switching element which is connected between a first input/output terminal and a second input/output terminal;
a control circuit configured to switch the bus switching element on when a signal is to be transmitted between the first and second input/output terminals;
first and second switching elements, each of which is connected between the second input/output terminal and a first voltage wiring, and is controlled in response to first and second control signals, respectively;
third and fourth switching elements, each of which is connected between the first input/output terminal and a second voltage wiring, and is controlled in response to third and fourth control signals, respectively, the second switching element being smaller in size than the first switching element and the fourth switching element being smaller in size than the third switching element; and
a signal generation circuit configured to generate the first and second control signals based on a result of a comparison between a first voltage applied to the first input/output terminal and a first threshold value and generate the third and fourth control signals based on a result of a comparison between a second voltage applied to the second input/output terminal and a second threshold value.
